(19) United States
(12) Patent Application Publication
(10) Pub. No.: US 2008/0128021 A1
(43) Pub. Date: Jun. 5, 2008

(54) NANOCOMPOSITE DEVICES, METHODS OF MAKING THEM, AND USES THEREOF

(75) Inventors: Kaushik Roy Choudhury, Gainesville, FL (US); Won Jin Kim, Daejeon (KR); Yudhisthira Sahoo, Amherst, NY (US); Kwang Sup Lee, Daejeon (KR); Paras N. Prasad, Williamsville, NY (US); Alexander Cartwright, Williamsville, NY (US); Ram B. Thapa, Amherst, NY (US)

Correspondence Address: NIXON PEABODY LLP - PATENT GROUP, 1100 CLINTON SQUARE, ROCHESTER, NY, 14604, US

(73) Assignee: The Research Foundation of State University of New York, Amherst, NY (US)

(21) Appl. No.: 11/850,929

(22) Filed: Sep. 6, 2007

Related U.S. Application Data
(60) Provisional application No. 60/824,686, filed on Sep. 6, 2006.

(51) Int. Cl. H01L 31/04; B05D 5/12

(52) U.S. Cl. 136/256; 427/74

(57) ABSTRACT

The present invention relates to a nanocomposite device comprising a polymeric matrix, semiconducting nanoparticles, and a semiconducting molecule having a field-effect mobility of at least 0.1 cm²/Vs. In addition, the present invention relates to a method of making a nanocomposite device. The method includes providing a mixture comprising a polymer, semiconducting nanoparticles, and a semiconducting molecule having a field-effect mobility of at least 0.1 cm²/Vs or a soluble precursor thereof, depositing the mixture on a substrate, and treating the mixture under conditions effective to produce a nanocomposite device comprising the polymeric matrix, semiconducting nanoparticles, and the semiconducting molecule having a field-effect mobility of at least 0.1 cm²/Vs. Thin film devices including the nanocomposite device are also disclosed.

This application claims the benefit of U.S. Provisional Patent Application Ser. No. 60/824,686, filed Sep. 6, 2006, which is hereby incorporated by reference in its entirety.

The subject matter of this application was made with support from the United States Government under the National Science Foundation, Grant No. DMR0318211 and AFOSR Grant No. F496200110358. The U.S. Government may have certain rights.

### FIELD OF THE INVENTION

The present invention relates to a nanocomposite device comprising a polymeric matrix, semiconducting nanoparticles, and a semiconducting molecule having a field-effect mobility of at least 0.1 cm²/Vs. In addition, the present invention relates to a method of making a nanocomposite device. The method includes providing a mixture comprising a polymer, semiconducting nanoparticles, and a semiconducting molecule having a field-effect mobility of at least 0.1 cm²/Vs or a soluble precursor thereof, depositing the mixture on a substrate, and treating the mixture under conditions effective to produce a nanocomposite device comprising the polymeric matrix, semiconducting nanoparticles, and the semiconducting molecule having a field-effect mobility of at least 0.1 cm²/Vs.

### BACKGROUND OF THE INVENTION

Conducting polymers, molecular organic semiconductors, nanocrystal quantum dots (QDs), and their composites have been employed in solid-state optoelectronic devices such as visible and infrared light-emitting diodes (Coe et al., “Electroluminescence from Single Monolayers of Nanocrystals in Molecular Organic Devices,” Nature 420:800-803 (Dec. 19, 2002); Tessler et al., “Efficient Near-Infrared Polymer Nanocrystal Light-Emitting Diodes,” Science, 295:1506-1508 (2002), which are hereby incorporated by reference in their entirety) and photodetectors (McDonald et al., “Solution-Processed PbS Quantum Dot Infrared Photodetectors and Photovoltaics,” Nature Materials, 4(2): 138-142 (2005); Qi et al., “Efficient polymer-nanocrystal quantum-dot photodetectors,” Applied Physics Letters, 86: 093103 (2005), which are hereby incorporated by reference in their entirety), field-effect transistors (Dodabalapur et al., “Organic Transistors: Two-Dimensional Transport and Improved Electrical Characteristics,” Science, 268:270-271 (1995); Afzali et al., “High-Performance, Solution-Processed Organic Thin Film Transistors from a Novel Pentacene Precursor,” J. Am. Chem. Soc., 124(30): 8812-8813 (2002), which are hereby incorporated by reference in their entirety), photovoltaic cells (Huynh et al., “Hybrid Nanorod-Polymer Solar Cells,” Science, 295:2425-2427 (2002); Granström et al., “Laminated Fabrication of Polymeric Photovoltaic Diodes,” Nature (London), 395: 257-260 (1998), which are hereby incorporated by reference in their entirety), and organic photorefractives (Winiarz et al., “Observation of the Photorefractive Effect in a Hybrid Organic-Inorganic Nanocomposite,” J. Am. Chem. Soc., 121(22): 5287-5295 (1999); Choudhury et al., “Nanocomposites for Infrared Photorefractivity at an Optical Communication Wavelength,” Adv. Mater., 17:2877-2881 (2005), which are hereby incorporated by reference in their entirety). The use of conjugated polymers in photodetection and photoconversion began in the early 1990's to achieve low-cost, solution-based, easily processable devices. However, pure polymeric devices have suffered the drawback of i) low mobility of charge carriers, ii) low photoconductivity (Barth et al., “Extrinsic and Intrinsic DC Photoconductivity in a Conjugated Polymer,” Physical Review B, 56(7): 3844-3851 (1997), which is hereby incorporated by reference in its entirety), and iii) limited range of spectral coverage. Inclusion of inorganic nanocrystal QDs as photosensitizers has not only enhanced charge generation and photoconduction efficiency (Choudhury et al., “Efficient Photoconductive Devices at Infrared Wavelengths Using Quantum Dot-Polymer Nanocomposites,” Appl. Phys. Lett., 87:073110 (2005), which is hereby incorporated by reference in its entirety), but also enabled broadening of the spectral coverage through their size-tunable optoelectronic properties.

Polymeric nanocomposite photovoltaic devices are composed of donor-acceptor components similar to organic photovoltaics (OPVs) (Xu et al., “4.2% Efficient Organic Photovoltaic Cells with Low Series Resistances” Appl. Phys. Lett., 84:3013-3015 (2004), which is hereby incorporated by reference in its entirety) but combine the advantages of flexibility in polymers (Brabec et al., “Plastic Solar Cells,” Adv. Funct. Mater., 11:15-26 (2001); Li et al., “High-Efficiency Solution Processable Polymer Photovoltaic Cells by Self-Organization of Polymer Blends” Nature Mater., 4:864-868 (2005); Kim et al., “New Architecture for High-Efficiency Polymer Photovoltaic Cells Using Solution-Based Titanium Oxide as an Optical Spacer,” Adv. Mater., 18:572-576 (2006), which are hereby incorporated by reference in their entirety) with the bandgap tunability of inorganic quantum dots (Huynh et al., “Hybrid Nanorod-Polymer Solar Cells,” Science, 295:2425-2427 (2002); McDonald et al., “Solution-Processed PbS Quantum Dot Infrared Photodetectors and Photovoltaics” Nat. Mater., 4:138-142 (2005); Zhang et al, “Enhanced Infrared Photovoltaic Efficiency in PbS Nanocrystal/Semiconducting Polymer Composites: 600-fold Increase in Maximum Power Output Via Control of the Ligand Barrier” Appl. Phys. Lett., 87:233101 (3 pages) (2005); Cui et al., “Harvest of Near Infrared Light in PbSe Nanocrystal-Polymer Hybrid Photovoltaic Cells” Appl. Phys. Lett., 88:183111 (3 pages) (2006), which are hereby incorporated by reference in their entirety). OPVs, in spite of their present photovoltaic conversion efficiency as high as 5% (Xu et al., “4.2% Efficient Organic Photovoltaic Cells with Low Series Resistances” Appl. Phys. Lett., 84:3013-3015 (2004); Li et al., “High-Efficiency Solution Processable Polymer Photovoltaic Cells by Self-Organization of Polymer Blends” Nature Mater., 4:864-868 (2005); Kim et al., “New Architecture for High-Efficiency Polymer Photovoltaic Cells Using Solution-Based Titanium Oxide as an Optical Spacer,” Adv. Mater., 18:572-576 (2006), which are hereby incorporated by reference in their entirety), still can not harvest the infrared (IR) photons. Thus, current OPV devices do not sufficiently exploit the entire solar spectrum since nearly 60% of the total solar photon flux resides at IR wavelengths beyond 700 nm. In this respect, hybrid nanocomposites are advantageous because the constituent QDs can provide photosensitization at many wavelengths including the IR (Brus, “Electron-Electron and Electron-Hole Interactions in Small Semiconductor Crystallites: The Size Dependence of the Lowest Excited Electronic State” J. Chem. Phys., 80:4403-4409 (1984); Prasad, Nanophotonics, Wiley, New York (2004), which are hereby incorporated by reference in their entirety). Hybrid nanocomposite solar cells have been reported with different polymers and QD compositions, most of them harvesting the visible light (Huynh et al., “Hybrid Nanorod-Polymer Solar Cells,” Science, 295:2425-2427 (2002), which is hereby incorporated by reference in its entirety) and very few responsive in the IR regime (McDonald et al., “Solution-Processed PbS Quantum Dot Infrared Photodetectors and Photovoltaics” Nat. Mater., 4:138-142 (2005); Zhang et al, “Enhanced Infrared Photovoltaic Efficiency in PbS Nanocrystal/Semiconducting Polymer Composites: 600-fold Increase in Maximum Power Output Via Control of the Ligand Barrier” Appl. Phys. Lett., 87:233101 (3 pages) (2005); Cui et al., “Harvest of Near Infrared Light in PbSe Nanocrystal-Polymer Hybrid Photovoltaic Cells” Appl. Phys. Lett., 88:183111 (3 pages) (2006), which are hereby incorporated by reference in their entirety). These devices still suffer from two main shortcomings of an organic matrix: short exciton migration length and low carrier mobility. To address these issues, bulk heterojunctions (Li et al., “High-Efficiency Solution Processable Polymer Photovoltaic Cells by Self-Organization of Polymer Blends” Nature Mater., 4:864-868 (2005); Yu et al., “Polymer Photovoltaic Cells: Enhanced Efficiencies via a Network of Internal Donor-Acceptor Heterojunctions,” Science, 270:1789-1791 (1995); Yang et al., “Controlled Growth of a Molecular Bulk Heterojunction Photovoltaic Cell” Nature Mater., 4:37-41 (2005); Peumans et al., “Efficient Bulk Heterojunction Photovoltaic Cells Using Small-Molecular-Weight Organic Thin Films” Nature, 425:158-162 (2003), which are hereby incorporated by reference in their entirety) consisting of interpenetrating networks of electron donor and acceptor components to facilitate excitonic dissociation throughout the device have been employed.

However, device performance of a polymer-nanoparticles nanocomposite is still limited by the intrinsically low mobility in polymeric organics.

On the other hand, several semiconducting organic molecules, which are of great interest for fabricating organic thin-film transistors (OTFTs), exhibit high field-effect mobilities (Yoo et al., “Efficient Thin-Film Organic Solar Cells Based on Pentacene/C60 Heterojunctions,” Applied Physics Letters, 85: 5427-5429 (2004); Klauk et al., “Pentacene Organic Transistors and Ring Oscillators on Glass and on Flexible Polymeric Substrates,” Applied Physics Letters, 82: 4175-4177 (2003), which are hereby incorporated by reference in their entirety). In particular, pentacene has one of the highest reported mobilities among organic materials (Nelson et al., “Temperature-Independent Transport in High-Mobility Pentacene Transistors,” Applied Physics Letters, 72:1854-1856 (1998); Klauk et al., “Pentacene Organic Transistors and Ring Oscillators on Glass and on Flexible Polymeric Substrates,” Applied Physics Letters, 82:4175-4177 (2003); Jurchescu et al., “Effect of Impurities on the Mobility of Single Crystal Pentacene,” Applied Physics Letters, 84: 3061-3063 (2004), which are hereby incorporated by reference in their entirety) and has mostly been studied as a p-type semiconductor in OTFTs (Nelson et al., “Temperature-Independent Transport in High-Mobility Pentacene Transistors,” Applied Physics Letters, 72:1854-1856 (1998); Klauk et al., “Pentacene Organic Transistors and Ring Oscillators on Glass and on Flexible Polymeric Substrates,” Applied Physics Letters, 82:4175-4177 (2003); Jurchescu et al., “Effect of Impurities on the Mobility of Single Crystal Pentacene,” Applied Physics Letters, 84: 3061-3063 (2004); Yoo et al., “Efficient Thin-Film Organic Solar Cells Based on Pentacene/C60 Heterojunctions,” Applied Physics Letters, 85:5427-5429 (2004), which are hereby incorporated by reference in their entirety). Large charge carrier mobility has been demonstrated recently in pentacene/C₆₀ heterojunction organic solar cells (Yoo et al., “Efficient Thin-Film Organic Solar Cells Based on Pentacene/C60 Heterojunctions,” Applied Physics Letters, 85:5427-5429 (2004), which is hereby incorporated by reference in its entirety), where the high photocurrent was attributed to the large excitonic diffusion length (˜65±16 nm) in pentacene. However, there has been no report of the use of pentacene in conjunction with nanoparticle-based polymeric composites. Moreover, there has been no report of the use of pentacene for infrared photodetection.

There exists an urgent need to realize sensitive infrared photodetectors for application in military and civilian sensing. Traditionally photodetection is realized with diodes made from polycrystalline inorganic semiconductors. While silicon is the universally accepted standard material for visible photodetection, extrinsically doped semiconductors like GaAs and AlGaAs are used to cover the infrared range. For all these inorganic semiconductors, obtaining materials of high purity and achieving the correct doping levels are critical to retain their sensitivity. GaAs/AlGaAs based Quantum Well Infrared Photodetectors have also been developed to operate in the IR range. These offer greater flexibility than the usual extrinsically doped semiconductor IR detectors because the wavelength of the peak response and cutoff can be continuously tailored over a broader range. However, all of these involve cost-intensive semiconductor processing techniques.

There are preceding reports to this invention that claim efforts at photodetection using organic polymers and inorganic semiconducting nanoparticles, both for the visible (Huynh et al., “Hybrid Nanorod-Polymer Solar Cells,” Science, 295(5564):2425-2427 (2002), which is hereby incorporated by reference in its entirety) and for the infrared (McDonald et al., “Solution-Processed PbS Quantum Dot Infrared Photodetectors and Photovoltaics,” Nat. Mater. 4(2):138-142 (2005), which is hereby incorporated by reference in its entirety). In all these efforts, although the inorganic semiconducting quantum dots have been effectively used to detect light energy from different parts of the electromagnetic spectrum, the overall performance of the devices are far from satisfactory. This is due to the fact that even though the use of inorganic semiconducting quantum dots offers high photogeneration efficiency through the formation of excitons i.e. electron-hole pairs, the actual device performance is ultimately limited by the speed with which the charge carriers (electrons and holes) are extracted from the quantum dots and transported to the respective electrodes, a step where the role of mobility of the organic matrix is crucial.

The present invention is directed to overcoming these and other deficiencies in the art.

### SUMMARY OF THE INVENTION

The present invention relates to a nanocomposite device comprising a polymeric matrix, semiconducting nanoparticles, and a semiconducting molecule having a field-effect mobility of at least 0.1 cm²/Vs.

Another aspect of the present invention relates to a method of making a nanocomposite device. The method includes providing a mixture comprising a polymer, semiconducting nanoparticles, and a semiconducting molecule having a field-effect mobility of at least 0.1 cm²/Vs or a soluble precursor thereof, depositing the mixture on a substrate, and treating the mixture under conditions effective to produce a nanocomposite device comprising the polymeric matrix, semiconducting nanoparticles, and the semiconducting molecule having a field-effect mobility of at least 0.1 cm²/Vs.

As claimed in the present invention, nanocomposites formed by the addition of high-mobility semiconducting molecules and semiconducting nanoparticles to a polymer matrix exhibit enhanced photoconductive performance. In particular, efficient photogeneration of carriers coupled with enhanced conductance results in high photoconductive quantum efficiency in the present invention. The present invention combines broad spectral access and band gap tunability enabled by semiconducting nanoparticles (different compositions and sizes having different band gaps) with enhanced carrier transport via high-mobility semiconducting molecules in a polymeric matrix, to realize hybrid nanocomposites and devices. Moreover, the devices of the present invention can be prepared by solution phase incorporation and processing of organic and inorganic components. Thus, inexpensive, low temperature solution processing of the devices on flexible substrates can be achieved. The demonstration of photodetection enhancement in a polymeric nanocomposite and in particular through the infrared telecommunication bands in accordance with the present invention is novel with significant implications to photovoltaics. By combining the high photogeneration efficiency, robustness against photobleaching and optical tunability of semiconducting nanoparticles with the flexibility and light weight characteristics of polymers, highly efficient large-area radiation resistant flexible IR photodetectors can be realized. The presently used conventional photodetector devices based on GaAs and AlGaAs depend on elaborate ultra-clean semiconductor growth technology, adding high cost to the devices. On the other hand, solution processing techniques of the present invention are much less expensive.

### BRIEF DESCRIPTION OF THE DRAWINGS

FIG. 1 shows a typical geometry of a device fabricated in accordance with the present invention.

FIG. 2 shows possible charge carrier pathways of a nanocomposite of the present invention. The overlapping π-electron systems of pentacene in a stacked geometry can enhance transport of photogenerated carriers. As shown, pentacene can form large enough local domains in close proximity to one another to form percolative pathways (shown by arrows).

FIG. 3 shows absorption spectra of a nanocomposite film of the present invention before and after annealing indicating the thermal conversion of a soluble precursor to pentacene in the film. Inset (a) shows TGA curves for the composite film and the precursor film. Inset (b) shows a TEM image of 5 nm PbSe QDs used in the composite film. Inset (c) shows the molecular structure of pentacene.

FIG. 4 shows conversion of a pentacene precursor to pentacene in accordance with the present invention.

FIG. 5A shows photocurrent density as a function of applied voltage in devices with the same proportion of PVK: pentacene (3:1) but varying amounts of PbSe nanocrystals as indicated in the legend. FIG. 5B shows photocurrent density as a function of applied bias at the operating wavelength of 1340 nm in different devices with varying proportions of PVK and pentacene.

FIG. 6 shows a comparison of the external quantum efficiency (EQE) of nanocomposite devices with varying amounts of PVK and pentacene. All samples include 25 wt % of PbSe nanocrystals.

FIG. 7 shows absorption spectra of PbSe QDs of different sizes used in an infrared active thin film polymeric photovoltaic device of the present invention. The excitonic absorption peak systematically shifts to higher wavelengths as the size increases.

FIG. 8 shows typical current density-voltage characteristics of hybrid photovoltaic devices in the dark (open circles) and under AM 1.5 illumination white light (triangles) with an intensity of 60 mW/cm².

FIG. 9 shows current density-voltage characteristics demonstrating the superior performance of a photovoltaic device incorporating pentacene (triangles) as compared to one without pentacene (circles) under AM 1.5 white light with an intensity of 60 mW/cm². The inset shows the typical infrared photocurrent response of the devices (with and without pentacene) when illuminated with white light passed through a 750 nm long pass filter.

FIG. 10 shows the energy band diagram of the components of a hybrid nanocomposite photovoltaic device. The schematic also depicts possible paths of photogenerated charge carriers in the case of exciton formation in PbSe QDs. The extra potential barrier originating from insulating ligand, such as oleic acid, is also pictorially depicted.

### DETAILED DESCRIPTION OF THE INVENTION

The present invention relates to a nanocomposite device comprising a polymeric matrix, semiconducting nanoparticles, and a semiconducting molecule having a field-effect mobility of at least 0.1 cm²/Vs.

A suitable polymeric matrix in accordance with the present invention can be chosen to obtain a nanocomposite device sensitive to light of different wavelengths. In particular, suitable polymeric matrices include, but are not limited to, poly-N-vinyl carbazole (PVK), poly(phenylene-vinylene) (PPV), a polythiophene (e.g., poly(3-hexylthiophene (P3HT)), and polyaniline (PANI). In one preferred embodiment, the polymeric matrix is PVK. In another preferred embodiment, the polymeric matrix is P3HT. P3HT is an excellent hole transporter with high mobility in the regioregular state (10⁻²-10⁻¹ cm²/Vs) and optical absorption up to about 650 nm.

Semiconducting nanoparticles for use in the present invention include inorganic nanoparticles. Such nanoparticles include, but are not limited to, quantum dots, core-shell semiconductor nanoparticles, such as CdSe (core)-ZnS (shell) particles and PbSe (core)-CdSe (shell) particles, bipods, tripods, and tetrapods. Suitable semiconducting quantum dots include, but are not limited to, ZnSe, ZnS, ZnTe, CdSe, CdS, CdTe, InP, InAs, InSb, PbSe, PbS, and PbTe. The semiconducting nanoparticles of the present invention may be chosen to obtain a nanocomposite sensitive to light of different wavelengths. For example, PbSe, PbS, PbTe, InSb, and InAs quantum dots may be used for devices in which infrared (IR) photodetection is desired; ZnSe and ZnS quantum dots may be used for devices in which ultraviolet (UV) photodetection is desired; and CdSe, CdS, CdTe, and InP quantum dots may be used for devices in which visible photodetection is desired.

In one preferred embodiment, the semiconducting nanoparticles are quantum dots. Quantum dots have been demonstrated to have discrete absorption and emission spectra by virtue of their quantum size effects. Quantum dot-based polymeric nanocomposite devices of the present invention can therefore enjoy the flexibility of addressing different spectral regions in the electromagnetic spectrum, including the IR region.

In another preferred embodiment, the semiconducting nanoparticles are PbSe quantum dots. PbSe quantum dots may be used as an IR photosensitizer in the nanocomposite of the present invention due to their low bulk band gap (0.26 eV) and the possibility of wavelength tunability due to excellent quantum confinement with a large Bohr radius (46 nm). Thus, tapping of all wavelengths over a broad solar spectral range from lower end up to the primary excitonic peak becomes possible with narrow spectral resolution. Additionally, the demonstration of ultra-high efficiency carrier multiplication by multiexciton generation in PbSe quantum dots (Schaller et al., “High Efficiency Carrier Multiplication in PbSe Nanocrystals: Implications for Solar Energy Conversion,” Phys. Rev. Lett. 92:186601 (4 pages) (2004); Shabaev et al., “Multiexciton Generation by a Single Photon in Nanocrystals,” Nano. Lett., 6:2856-2863 (2006), which are hereby incorporated by reference in their entirety) makes these quantum dots promising candidates for very efficient harvesting of solar photons also in the ultraviolet region by the probably process of multiexciton generation.

In yet another embodiment, the nanoparticles include one or more surface coatings or surface ligands. Suitable surface coatings and surface ligands are known in the art and include, but are not limited to, trioctylphosphione oxide, tributyphosphine oxide, myristic acid, oleic acid, oleyl amine, tributylamine, pyridine, and dodecanethiol.

Suitable semiconducting molecules having a field-effect mobility of at least 0.1 cm²/Vs include organic and inorganic molecules. For example, suitable semiconducting molecules having a field-effect mobility of at least 0.1 cm²/Vs include, but are not limited to, polycyclic aromatic compounds and metal chalcogenides (Mitzi et al., “Low Voltage Transistor Employing a High-Mobility Spin-Coated Chalcogenide Semiconductor,” Adv. Mater. 17:1285 (2005); Mitzi et al., “High-Mobility Ultrathin Semiconducting Films Prepared by Spin Coating,” Nature, 428:299 (2004); Kagan et al., “Organic-Inorganic Hybrid Materials as Semiconducting Channels in Thin-Film Field-Effect Transistors,” Science, 286:945 (1999), which are hereby incorporated by reference in their entirety). Examples of semiconducting molecules having a high field-effect mobility according to the present invention include, but are not limited to, pentacene, tetracene, rubrene, and anthracene.

In one preferred embodiment, the semiconducting molecule having a field-effect mobility of at least 0.1 cm²/Vs is a polycyclic aromatic compound, such as pentacene. In particular, pentacene has one of the highest reported mobilities among organic materials (Nelson et al., “Temperature-Independent Transport in High-Mobility Pentacene Transistors,” Applied Physics Letters, 72:1854-1856 (1998); Klauk et al., “Pentacene Organic Transistors and Ring Oscillators on Glass and on Flexible Polymeric Substrates,” Applied Physics Letters, 82:4175-4177 (2003); Jurchescu et al., “Effect of Impurities on the Mobility of Single Crystal Pentacene,” Applied Physics Letters, 84: 3061-3063 (2004), which are hereby incorporated by reference in their entirety). More specifically, in the nanocomposites of the present invention, pentacene, with its highest occupied molecular orbital and lowest unoccupied molecular orbital at 5.2 and 3.1 eV, respectively, forms a donor/acceptor heterojunction with the semiconducting nanoparticles, promotes the dissociation of photogenerated excitons, and facilitates the transfer of holes from the semiconducting nanoparticles.

Preferably, a nanocomposite device of the present invention includes 37 to 60 wt % polymer, 5 to 25 wt % semiconducting nanoparticles, and 15 to 37 wt % semiconducting molecule having a field-effect mobility of at least 0.1 cm²/Vs.

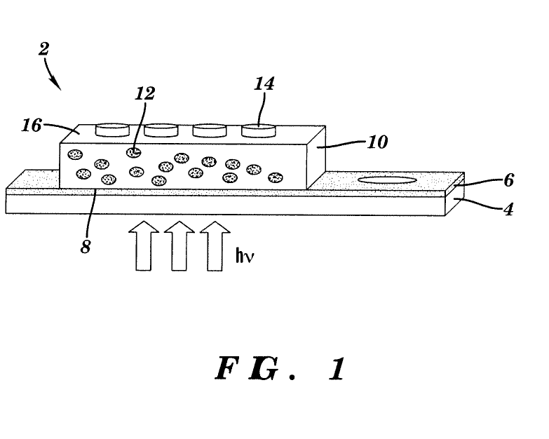

The nanocomposites of the present invention can be used for fabrication of thin film devices, such as photodetectors, sensors, solar cells, photovoltaics, and related device structures. Accordingly, the present invention also relates to a thin film polymeric device comprising a nanocomposite of the present invention in contact with first and second electrodes, wherein the first and second electrodes are positioned to collect electrons, holes, or both such that the device functions as a photodetector or photovoltaic device. Typical geometry of a photodetector or photovoltaic device in accordance with the present invention is shown in FIG. 1. In particular, the device 2 includes a substrate 4 having a first electrode 6 deposited thereon. A first surface 8 of nanocomposite layer 10 is positioned adjacent the first electrode 6. The nanocomposite layer 10 comprises a polymeric matrix, one or more semiconducting nanoparticles 12, and a semiconducting organic molecule having a field-effect mobility of at least 0.1 cm²/Vs. One or more second electrodes 14 are positioned adjacent a second surface 16 of the nanocomposite layer. The first and second electrodes are positioned so that the device can function as a photodetector (with external bias) or photovoltaic device (without external bias). Suitable substrates and first and second electrodes for forming a photodetector or photovoltaic device are known in the art and are described, for example, in Peumans et al., “Small Molecular Weight Organic Thin-Film Photodetectors and Solar Cells,” J. App. Phys., 93:3693 (2003), U.S. Pat. No. 7,173,369, and U.S. Pat. No. 6,972,431, which are hereby incorporated by reference in their entirety.

In accordance with the present invention, the combination of semiconducting nanoparticles with semiconducting molecules having a field-effect mobility of at least 0.1 cm²/Vs in a polymer matrix allows the formation of devices with a preferential spectral response in the near IR spectral regions, including the technologically important telecommunications wavelengths of 1.3 nm and 1.55 nm. In particular, for semiconducting nanoparticles, control over particle size translates into the ability to control the magnitude of the band gap (i.e., quantum confinement effect). Thus, the careful selection of the polymer matrix and semiconducting nanoparticles provides precise control over the spectral sensitivity of the resulting device. In particular, devices of the present invention may achieve highly efficient IR photodetection and photoconductivity through the use of inorganic semiconducting nanoparticles to successfully photosensitize a polymeric composite at infrared wavelengths and the incorporation of a high-mobility semiconductor to assist and boost charge transport in the polymeric devices.

In one preferred embodiment of the present invention, a thin film device including PbSe QDs and pentacene in a PVK matrix achieves highly efficient IR photodetection and photoconductivity. Efficient harvesting of IR photo-generated carriers by the PbSe QDs, and enhanced transport and conductance in the polymeric matrix boosted by pentacene, leads to the highest photoconductive quantum efficiency achieved till date in polymeric devices at telecommunication wavelengths (see Examples, below).

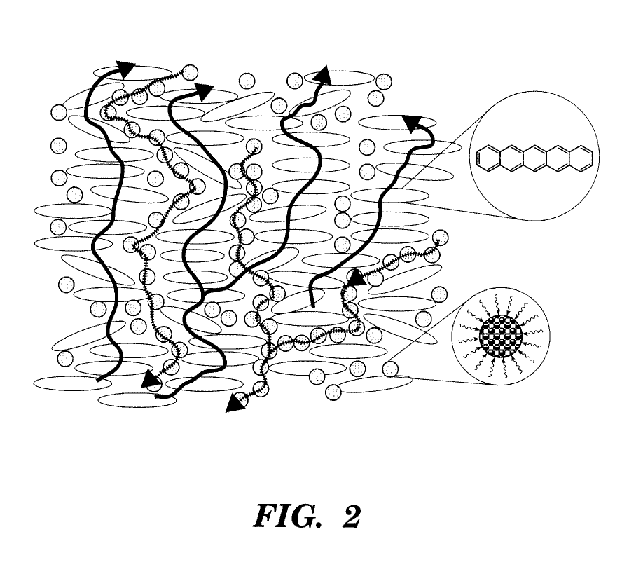

A schematic of the possible pathway of charge carriers in a nanocomposite device of the present invention is shown in FIG. 2. Overlapping π-electron systems of pentacene in a stacked geometry can enhance transport of the generated carriers. At a suitable concentration, pentacene forms large enough local domains in close proximity to one another leading to percolative pathways (shown by arrows) for charge carriers.

Another aspect of the present invention relates to a method of making a nanocomposite device. The method includes providing a mixture comprising a polymer, semiconducting nanoparticles, and a molecule having a field-effect mobility of at least 0.1 cm²/Vs or a soluble precursor thereof, depositing the mixture on a substrate, and treating the mixture under conditions effective to produce a nanocomposite device comprising the polymeric matrix, semiconducting nanoparticles, and the semiconducting molecule having a field-effect mobility of at least 0.1 cm²/Vs.

In accordance with the present invention, deposition can be achieved by methods known in the art including, but not limited to, spin coating, drop casting, and doctor blading. Suitable substrates include, but are not limited to, glass (with or without, for example, electrode coatings), polyethylene terephthalate (PET), and metallic foils.

In one embodiment of the present invention, treating comprises drying the mixture to form a nanocomposite film. In particular, drying can be achieved by evaporation or heating of the mixture to remove any solvent in the mixture and form a film.

In one preferred embodiment of the method of the present invention, a soluble precursor for the semiconducting molecule having a field-effect mobility of at least 0.1 cm²/Vs is used in the mixture. In this preferred embodiment, treating further comprises converting the soluble precursor into the semiconducting molecule having a field-effect mobility of at least 0.1 cm²/Vs. Suitable techniques for converting the soluble precursor to the semiconducting molecule having a field-effect mobility of at least 0.1 cm²/Vs will be determined by the choice of soluble precursor and can be determined by one of ordinary skill in the art.

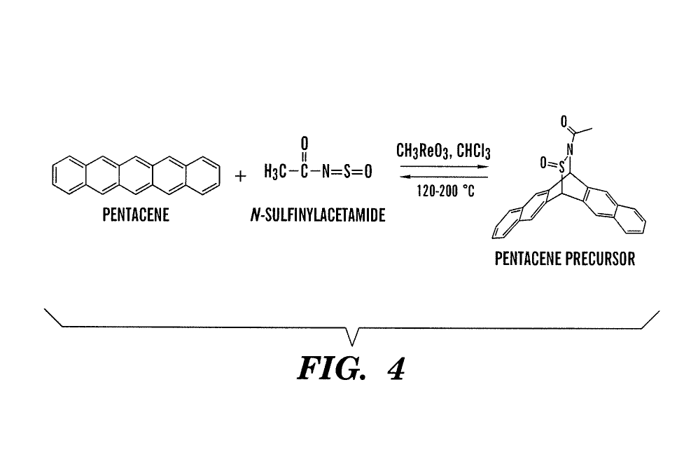

In another preferred embodiment, the soluble precursor is a soluble precursor to pentacene. The soluble precursor to pentacene can be converted to pentacene in situ by heat treatment. In particular, the aromatic polycyclic pentacene suffers from the drawback of being insoluble in most common organic solvents. This poses a problem towards maintaining inexpensive, low temperature solution processing of devices on flexible substrates. In accordance with the present invention, this drawback is circumvented by using a soluble precursor to pentacene, as shown in FIG. 4. This method can be generalized to nanocomposites of many different compositions by using different semiconducting nanoparticles and other polymeric matrices to obtain active devices sensitive to light of different wavelengths.

### EXAMPLES

### Example 1

### Synthesis of PbSe Quantum Dots

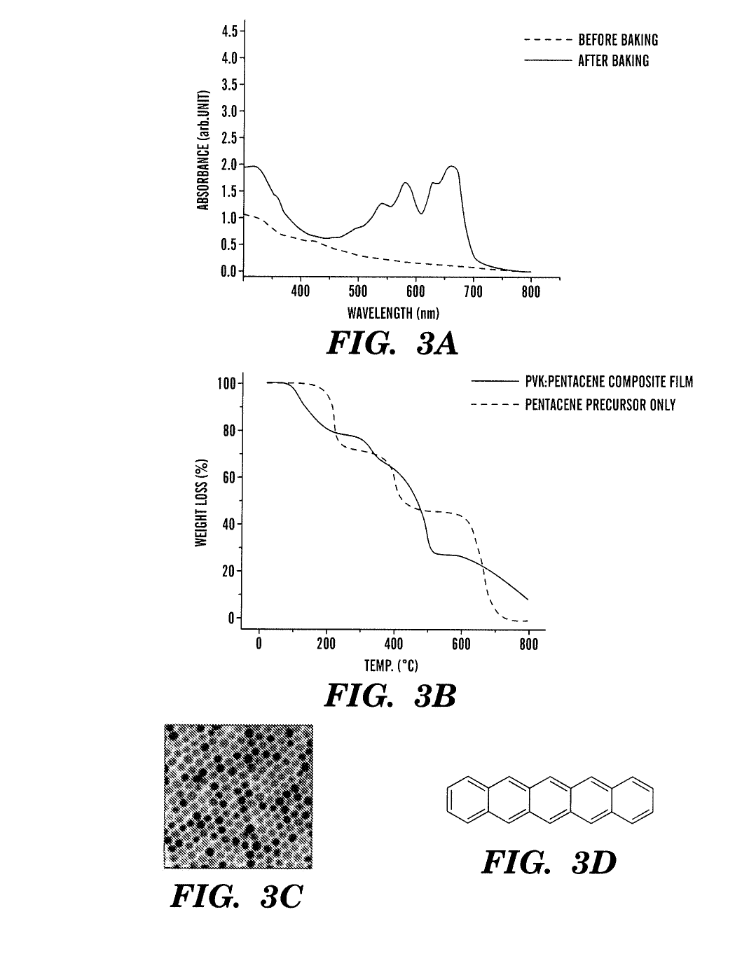

Discretely sized (Inset (b) of FIG. 3) PbSe QDs were prepared by a hot colloidal route using organically soluble precursors (Choudhury et al., “Efficient Photoconductive Devices at Infrared Wavelengths Using Quantum Dot-Polymer Nanocomposites,” Appl. Phys. Lett., 87:073110 (2005), which is hereby incorporated by reference in its entirety). PbO (5 mmol) and oleic acid (25 mmol) were added to 20 mL tri-n-octyylamine. The reaction mixture was heated under alternate vacuum and argon atmosphere for 30 minutes at 155° C., when 10 mL 1M TOP-Se (i.e. selenium dissolved in tri-n-octylphosphine) was rapidly injected into the reaction flask. The reaction took place instantaneously giving rise to uniform sized PbSe QDs. The product was syringed out in different fractions as a function of time from the reaction mixture and quenched in toluene. The QDs were cleaned off to remove excess surfactant oleic acid and other side products by precipitation with excess acetone added to an aliquot followed by centrifugation. The final product was dispersed in chloroform yielding a clear dispersion.

### Example 2

### Preparation of a Soluble Precursor to Pentacene

The soluble pentacene precursor was prepared by the Diels-Alder reaction between pentacene and N-sulfinylacetamide, following Afzali et al., “High-Performance, Solution-Processed Organic Thin Film Transistors from a Novel Pentacene Precursor,” J. Am. Chem. Soc., 124(30): 8812-8813 (2002), which is hereby incorporated by reference in its entirety. In particular, N-sulfinylacetamide (840 mg, 8 mmol) was added to pentacene (556 mg, 2 mmol) and methyltrioxorhenium (30 mg, 0.12 mmol) in chloroform (30 mL). The mixture was refluxed for 12 hours and filtered after cooling. The product was purified by flash column chromatography (silica gel; chloroform). The resulting material was easily converted to pentacene by the retro Diels-Alder reaction under various backing temperatures, as shown in FIG. 4.

### Example 3

### Introduction of Soluble Pentacene Precursor and Composite Device Fabrication

In a typical device fabrication procedure, the organic polymer PVK and the pentacene precursor in different proportions were dissolved in a known volume chloroform. Chloroform dispersions of oleic acid-capped PbSe QDs (with absorption tuned to 1340 nm) were then added and the composite solution was homogenized by vigorous stirring and ultrasonication, before being spin-cast on an indium tin oxide (ITO)-coated glass substrate to yield composite thin films. The resulting samples were dried overnight in vacuum to ensure complete solvent removal. Next, the dried films were annealed at 200° C. to let the precursor undergo thermolysis to generate pentacene in situ (FIG. 4). Finally, aluminum electrodes were thermally evaporated through a shadow mask to yield devices with active area ˜0.04 cm² (FIG. 1). The average thickness of the composite film was determined to be about 100 nm.

The absorption spectra of the devices were obtained with a Shimazdu 3101 spectrophotometer. The thermogravimetric analysis (TGA) spectograms were taken on a Perkin Elmer instrument model TGA7. Photoconductivity measurements were performed under ambient conditions using a Keithley 2400 source measurement unit interfaced with LABVIEW software for data acquisition. Optical excitation was provided by a continuous-wave semiconductor laser operating at 1340 nm, having about 100 mW/cm² output power.

### Example 4

### Characterization of the Hybrid Composite Device

In order to confirm that effective thermal conversion of the pentacene precursor had occurred in situ, TGA of the composite film was performed. The TGA curves of the composite films showed a retarded weight loss profile compared to the neat pentacene precursor, but the essential steps (Afzali et al., “High-Performance, Solution-Processed Organic Thin Film Transistors from a Novel Pentacene Precursor,” J. Am. Chem. Soc., 124(30): 8812-8813 (2002), which is hereby incorporated by reference in its entirety) depicting weight loss due to a retro-Diels-Alder reaction were retained (inset (a) of FIG. 3). Additionally, characteristic absorption peaks appearing in the annealed films between 500 and 700 nm indicated the formation of pentacene within the film (Afzali et al., “High-Performance, Solution-Processed Organic Thin Film Transistors from a Novel Pentacene Precursor,” J. Am. Chem. Soc., 124(30): 8812-8813 (2002), which is hereby incorporated by reference in its entirety) (FIG. 3).

### Example 5

### Efficient Photodetection with Hybrid Nanocomposite at IR Wavelengths

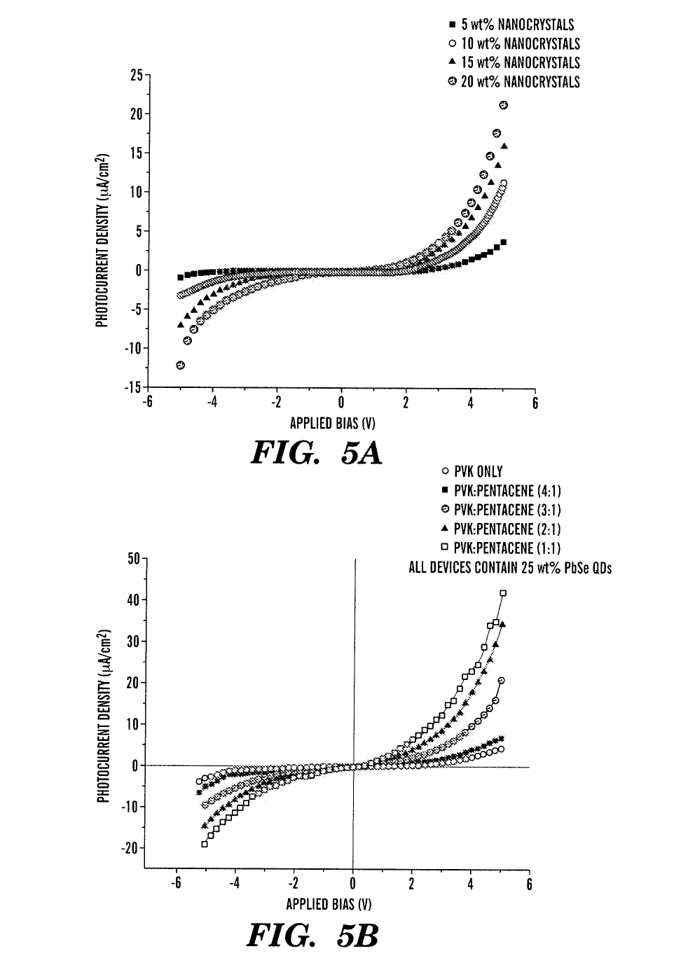

Different ratios of the constituents in the composite blend were explored. For a given proportion of PVK to pentacene precursor (3:1), the PbSe QD content was varied from about 5 wt % to about 25 wt % of the composite. FIG. 5A shows measured photocurrents at the operating wavelength of 1340 nm in different composites with the ratio of PVK to pentacene maintained at 3:1 and the PbSe QD contents varied from about 5 wt % to about 25 wt % of the composite. Further increase in nanoparticle concentration beyond this led to device breakdown. At a high concentration of PbSe QDs, photogeneration of excitons was greatly enhanced (Winiarz et al., “Observation of the Photorefractive Effect in a Hybrid Organic-Inorganic Nanocomposite,” J. Am. Chem. Soc., 121(22): 5287-5295 (1999); Choudhury et al., “Nanocomposites for Infrared Photorefractivity at an Optical Communication Wavelength,” Adv. Mater., 17:2877-2881 (2005), which are hereby incorporated by reference in their entirety), contributing to an increase in the photocurrent density (FIG. 5A). Efficient dissociation of the photogenerated excitons at the QD/polymer and QD/pentacene interfaces was followed by the conduction of photogenerated carriers via appropriate pathways in PVK and pentacene. The π-bonded stacked structure of pentacene enhanced the mobility of the generated carriers, leading to improved photoconductance.

The measured photocurrent densities as a function of applied bias for devices with increasing amounts of pentacene are shown in FIG. 5B. The photocurrent increased significantly as the amount of pentacene in the composite increased (FIG. 5B). The best performance was extracted in devices with equal amounts of PVK and pentacene (having about 25 wt % of PbSe QDs). The enhancement in photocurrent, compared to a PVK-PbSe film, was more than eight times. For all the measured devices, it is worthy to note that the dark current is always very small, about 10⁻⁸ A, due to the overall insulating nature of the thin film device. Thus, it is unambiguous that the enhanced charge carrier generation and efficient transport lead to ratios of photo- to dark current >>100.

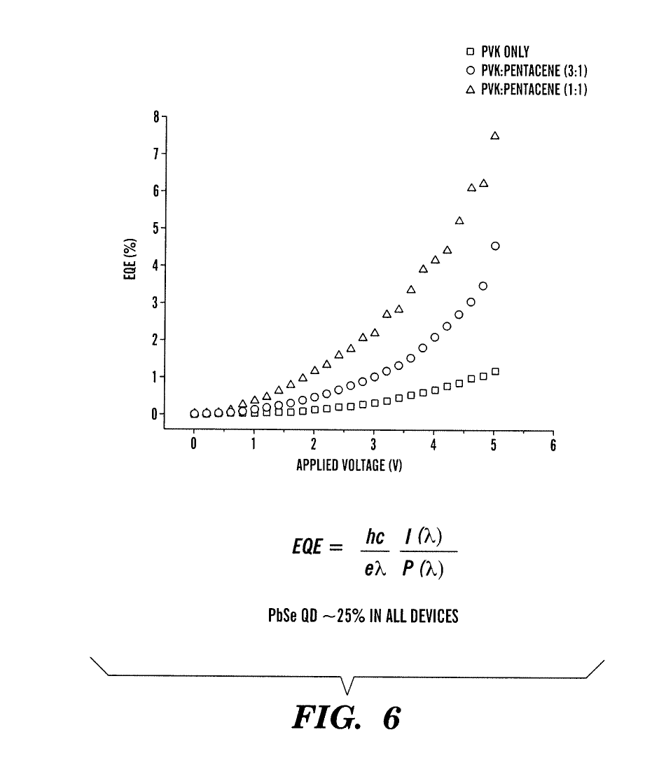

The parameter that determines the efficiency of photoconduction in such devices is the external quantum efficiency (EQE) defined as the ratio of the number of collected charges at the electrode to the number of incident photons at the operating wavelength. FIG. 6 presents the EQEs of three devices with the same concentration of nanoparticles (about 25 wt %), but with different proportions of pentacene to PVK. A maximum EQE of about 8 % at an applied device bias of 5 V was achieved in the composite having equal amounts of PVK and pentacene. This is an improvement of eight times over the PVK-PbSe devices under similar experimental conditions, and is a spectacular improvement over all earlier results with such hybrid composites (McDonald et al., “Solution-Processed PbS Quantum Dot Infrared Photodetectors and Photovoltaics,” Nature Materials, 4(2): 138-142 (2005); Qi et al., “Efficient polymer-nanocrystal quantum-dot photodetectors,” Applied Physics Letters, 86: 093103 (2005) Choudhury et al., “Efficient Photoconductive Devices at Infrared Wavelengths Using Quantum Dot-Polymer Nanocomposites,” Appl. Phys. Lett., 87:073110 (2005), which are hereby incorporated by reference in their entirety). Since the composites of the present invention contain a lower fraction of QDs than that used in earlier studies, the augmentation of the photoconduction quantum efficiency can be unequivocally attributed to the inclusion of pentacene, having high field-effect mobility, in the composite.

### Example 6

### Synthesis of an IR Active Thin Film Polymeric Photovoltaic Device

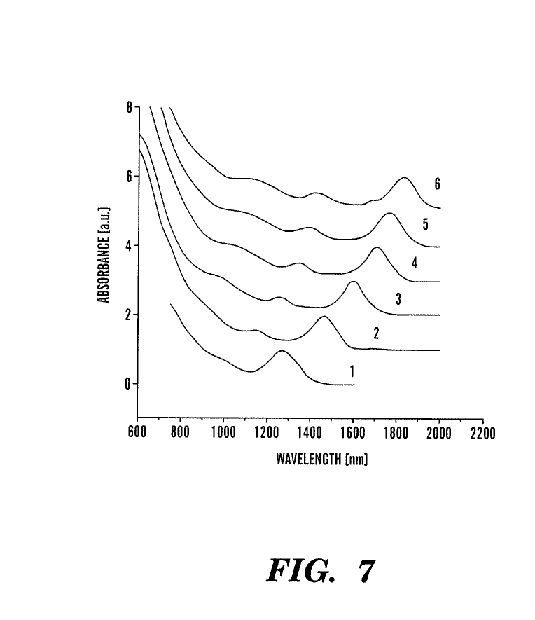

PbSe QDs were prepared by a hot colloidal synthetic method as described in Example 1 (Murray et al., “Synthesis and Characterization of Monodispersed Nanocrystals and Close-Packed Nanocrystal Assemblies” Annu. Rev. Mat. Sci., 30:545-610 (2000), which is hereby incorporated by reference in its entirety), yielding highly uniform QDs as evident in the transmission electron microscopy (TEM) images (FIG. 3, inset b) and narrow excitonic peaks shown in plots 1-6 for different sized particles (FIG. 7). In particular, absorbance spectra of PbSe quantum dots of different sizes from about 2.8 nm (plot 1) to about 8 nm (plot 6) in solvent tetrachloroethylene are shown in FIG. 7. The discrete absorbance maxima span over the infra red as the quantum dot sizes gradually increase. In order to retain the advantageous solution processing of devices, a soluble precursor to pentacene (Afzali et al., “High-Performance, Solution-Processed Organic Thin Film Transistors from a Novel Pentacene Precursor” J. Am. Chem. Soc., 124: 8812-8813 (2002)) was prepared, as described in Example 2. Photovoltaic devices were fabricated on ITO coated glass substrates (40±10 Ω/sq sheet resistance) used as the bottom anode. After routine solvent cleaning (sequentially with acetone, methanol, and deionized water), the substrate was coated with a thin (˜130 nm) buffer layer of poly(3,4-ethylenedioxythiophene):poly(styrenesulfonate) (PEDOT:PSS), and baked at 180° C. for 15 minutes, a treatment that serves to minimize effects of pin-holes on the ITO surface and eliminate unwarranted shorts. Details of the device fabrication follow closely the procedure outlined in Examples 3-4, above. Thermal annealing of the thin-film device in nitrogen at 205° C. for 10 minutes converted the precursor to pentacene within the matrix. In order to confirm the role of pentacene, two devices (with and without pentacene) were fabricated using exactly the same procedures and under identical conditions. The stoichiometries were 54:23:23 of PbSe QD:Pentacene:P3HT and 70:30 PbSe:P3HT by weight for devices with and without pentacene, respectively.

Current density-voltage measurements in dark and under illumination were performed in the ambient with a Kiethley 2400 source meter. Illumination was provided by an Oriel xenon lamp. The mismatch of the simulated spectrum from the xenon lamp and an actual solar spectrum was minimized by using an AM 1.5 G filter, while the incident intensity was adjusted to 60 mWcm⁻².

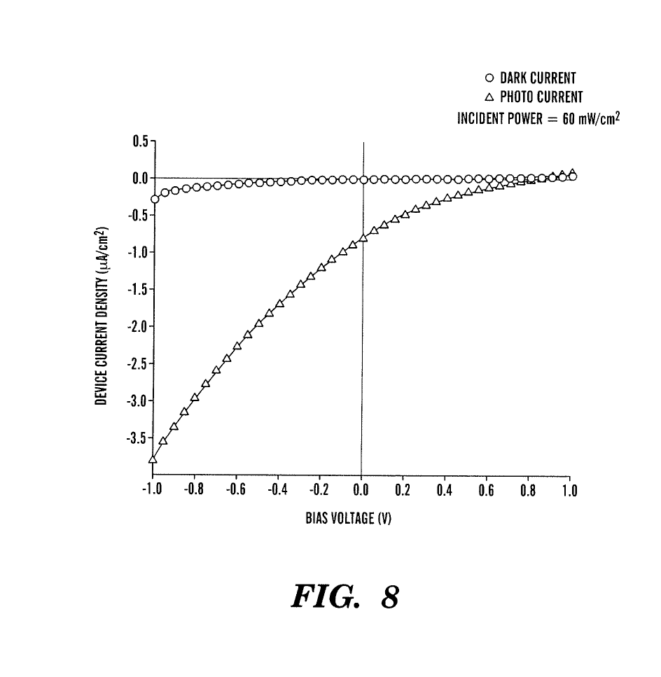

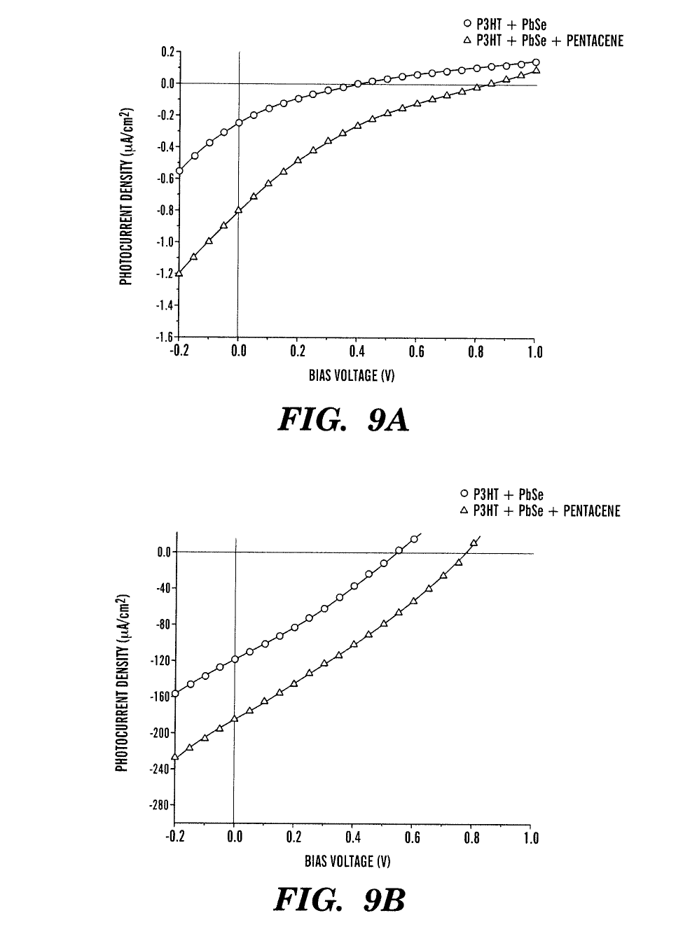

In FIG. 8, the dark current and photocurrent densities obtained in the device with pentacene are shown as a function of applied bias at the ITO electrode. The device exhibited a typical diode-like behavior with higher photocurrents in the reverse bias and typical photovoltaic characteristic at zero bias. FIG. 9 demonstrates representative photovoltaic response in the two types of devices. The enhancement of device performance from the inclusion of pentacene can be directly observed in the current-density versus voltage (J-V) curves under white light illumination. In the device without pentacene, a short-circuit current (J_{SC}) of 239 nAcm⁻² and an open-circuit voltage (V_{OC}) of 0.37 V were observed and for the device with pentacene, J_{SC} increased to 800 nAcm⁻² while V_{OC} was enhanced to 0.818 V, resulting in a fill-factor (FF) of 0.163. This clearly demonstrates a significant improvement in J_{SC} (by 57%) and V_{OC} (by 43%) by including pentacene, thus a six-fold improvement in the overall photovoltaic efficiency. However, the current density obtained may be optimized, because proper surface ligand changes on the QD surfaces, optimization of load fraction of QDs in the nanocomposite, film thickness and annealing treatment may lead to better performance of the device. The rather low FF can be understood in the light of a high cumulative series resistance of the device, which can be improved by optimizing the aforementioned factors.

Each of the constituents of the present composite is photoactive, with different regimes of spectral sensitivity. Whereas P3HT and pentacene are active mostly in the shorter wavelengths, with very little optical absorption beyond 600 nm and 700 nm respectively (Brabec et al., “Plastic Solar Cells,” Adv. Funct. Mater., 11:15-26 (2001); Li et al., “High-Efficiency Solution Processable Polymer Photovoltaic Cells by Self-Organization of Polymer Blends” Nature Mater., 4:864-868 (2005); Kim et al., “New Architecture for High-Efficiency Polymer Photovoltaic Cells Using Solution-Based Titanium Oxide as an Optical Spacer,” Adv. Mater., 18:572-576 (2006); Afzali et al., “High-Performance, Solution-Processed Organic Thin Film Transistors from a Novel Pentacene Precursor” J. Am. Chem. Soc., 124: 8812-8813 (2002); Choudhury et al., “Solution-Processed Pentacene Quantum-Dot Polymeric Nanocomposite for Infrared Photodetection” Appl. Phys. Lett., 89:051109 (3 pages) (2006), which are hereby incorporated by reference in their entirety), the photosensitivity of the PbSe QDs extends to the IR with the first excitonic peak occurring at 1470 nm (0.84 eV). Thus, short wavelengths (<700 nm) would be absorbed by PbSe as well as by P3HT, whereas wavelengths in the IR portion (>700 nm) would be tapped by only the PbSe QDs. The ability of the photovoltaic cell to harness the IR part of the solar spectrum is depicted in the inset of FIG. 9 where photosensitization was caused only by the IR portion of white light from a Xenon lamp by placing a long pass filter with cutoff at 750 nm. In Cui et al. “Harvest of Near Infrared Light in PbSe Nanocrystal-Polymer Hybrid Photovoltaic Cells” Appl. Phys. Lett., 88:183111 (3 pages) (2006), which is hereby incorporated by reference in its entirety, a 780 nm long pass cutoff filter decreased the overall photovoltaic efficiency to 33% of the original, but the responsivity of PbSe QDs to the IR light was well established. In the present example, it is shown that the IR responsivity of the device is clearly boosted by the inclusion of pentacene.

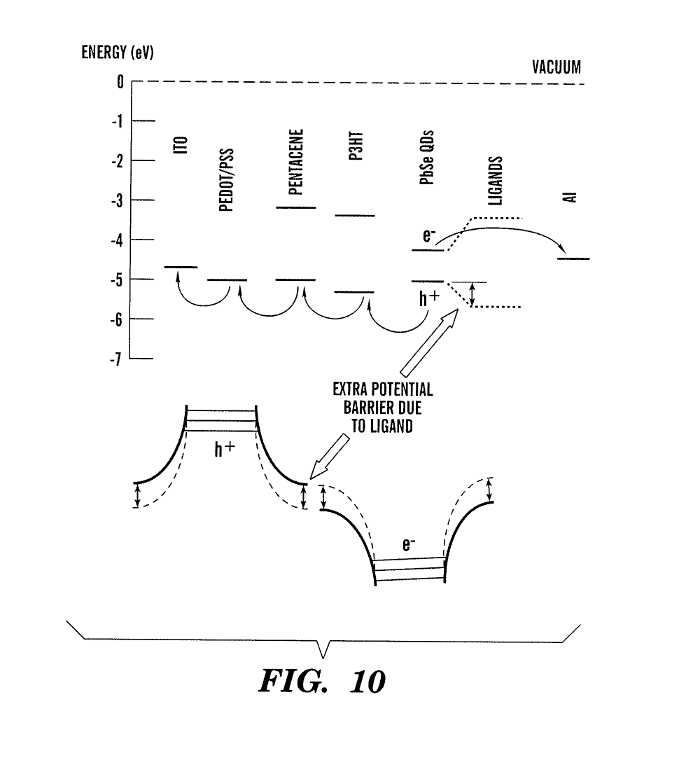

The energy band alignments of the constituent materials are depicted in FIG. 10. The ionization potential of P3HT lying closer to the vacuum, suggests a favorable heterojunction with the QDs for excitonic dissociation implying transfer of electrons to the PbSe QDs, that of holes to P3HT and onto the respective electrodes. The magnitude of the photovoltaic current depends on the effective impedance within the nanocomposite where substantial resistive elements can arise from different loss mechanisms viz. recombination of free carriers, carrier traps, barriers impeding charge transport and so on. It is also generally accepted that the disordered energy landscape of polymeric components and inherent space-charge effects of bulk heterojunctions leads to a high series resistance (Yu et al., “Polymer Photovoltaic Cells: Enhanced Efficiencies via a Network of Internal Donor-Acceptor Heterojunctions,” Science, 270:1789-1791 (1995); Yang et al., “Controlled Growth of a Molecular Bulk Heterojunction Photovoltaic Cell” Nature Mater., 4:37-41 (2005); Peumans et al., “Efficient Bulk Heterojunction Photovoltaic Cells Using Small-Molecular-Weight Organic Thin Films” Nature, 425:158-162 (2003), which are hereby incorporated by reference in their entirety) in such devices. Moreover, there is a substantial resistance at the surface of the QDs due to the presence of insulating surfactant layer(s), despite washing away excess amounts of surfactants. It is generally believed that, in such hybrid nanocomposites, the holes move towards the cathode through the network of polymeric chains via the mechanism of dispersive transport and the electrons move by a hopping between nanoparticles (Choudhury et al., “Charge Carrier Transport in Poly(N-vinylcarbazole):CdS Quantum Dot Hybrid Nanocomposite,” J. Phys. Chem. B, 108:1556-1562 (2004); Huynh et al., “Charge Transport in Hybrid Nanorod-Polymer Composite Photovoltaic Cells” Phys. Rev. B, 67:115326 (2003), which are hereby incorporated by reference in their entirety) and also shallow electron trap sites (Huynh et al., “Charge Transport in Hybrid Nanorod-Polymer Composite Photovoltaic Cells” Phys. Rev. B, 67:115326 (2003), which is hereby incorporated by reference in its entirety) within the nanocomposite. In line with this proposed model, introducing a less resistive pathway for the conduction of either carrier would enhance the device current. Pentacene was chosen because it could provide such a high mobility route due to its favorable band alignment (FIG. 10) for the transport of holes from the QDs. High field-effect mobility (about 1 cm²/Vs) has been demonstrated in pentacene through careful annealing (Herwig et al., “A Soluble Pentacene Precursor: Synthesis, Solid-State Conversion into Pentacene and Application in a Field-Effect Transistor,” Adv. Mater., 11:480-483 (1999), which is hereby incorporated by reference in its entirety), whereby π-electron bonded stacked structures are formed. In this example, pentacene was generated in situ by thermal conversion of its soluble precursor within the polymeric nanocomposite. The overlapping π-electron systems in the stacked geometry appear to produce conducting domains within the nanocomposite and enhance transport of the carriers. Although dispersing the pentacene precursor in the mixed system and its in situ formation would disrupt the stacking structure to some extent, it is believed that the pentacene still forms large enough local domains in close proximity to one another, leading to low resistive conduction pathways. It could be questioned that the increase of photovoltaic efficiency could also result from the independent photovoltaic effect at the pentacene:QD heterojunctions by white light that would offer only an additive role to the overall efficiency of the device. However, the following considerations make the conclusion that pentacene primarily participates as a mobility booster rather than another photovoltaic component, unequivocal: (i) inclusion of pentacene enhanced the photoconductivity efficiency in the previous examples conducted on the nanocomposite PVK/PbSe/pentacene at the IR wavelength 1340 nm where absorption by pentacene does not exist; (ii) a confirmatory test on the nanocomposite of the present example showed that even when a 750 nm long pass filter was used, the J_{SC} and V_{OC} values of the device were still enhanced (FIG. 9, inset). Thus, although the effect of pentacene as an independent photovoltaic component cannot be ruled out, its assistive participation in facilitating carrier mobility in the nanocomposite is undeniable.

Although preferred embodiments have been depicted and described in detail herein, it will be apparent to those skilled in the relevant art that various modifications, additions, substitutions, and the like can be made without departing from the spirit of the invention and these are therefore considered to be within the scope of the invention as defined in the claims which follow.

1. A nanocomposite device comprising:
a polymeric matrix;
semiconducting nanoparticles; and
a semiconducting molecule having a field-effect mobility of at least 0.1 cm²/Vs.

2. The nanocomposite device according to claim 1, wherein the polymeric matrix is poly-N-vinyl carbazole, poly(phenylene-vinylene), a polythiophene, or polyaniline.

3. The nanocomposite device according to claim 2, wherein the polymeric matrix is poly-N-vinyl carbazole.

4. The nanocomposite device according to claim 2, wherein the polymeric matrix is poly(3-hexylthiophene).

5. The nanocomposite device according to claim 1, wherein the semiconducting nanoparticles are quantum dots, core-shell semiconductor nanoparticles, bipods, tripods, or tetrapods.

6. The nanocomposite device according to claim 5, wherein the semiconducting nanoparticles are quantum dots selected from the group consisting of ZnSe, ZnS, ZnTe, CdSe, CdS, CdTe, InP, InAs, InSb, PbSe, PbS, and PbTe.

7. The nanocomposite device according to claim 1, wherein the semiconducting molecule having a field-effect mobility of at least 0.1 cm²/Vs is a polycyclic aromatic compound or metal chalcogenide.

8. The nanocomposite device according to claim 7, wherein the semiconducting molecule having a field-effect mobility of at least 0.1 cm²/Vs is a polycyclic aromatic compound.

9. The nanocomposite device according to claim 8, wherein the semiconducting molecule having a field-effect mobility of at least 0.1 cm²/Vs is pentacene.

10. The nanocomposite device according to claim 1, wherein the device comprises 37 to 60 wt % polymer, 5 to 25 wt % semiconducting nanoparticles, and 15 to 37 wt % semiconducting molecule having a field-effect mobility of at least 0.1 cm²/Vs.

11. A thin film polymeric device comprising:
a nanocomposite device according to claim 1 having a first surface in contact with a first electrode and a second surface in contact with a second electrode, wherein said first and second electrodes are positioned to allow transfer of electrons, holes, or both through the nanocomposite device to the first and second electrodes.

12. The thin film polymeric device according to claim 11, wherein the thin film polymeric device is a photodetector.

13. The thin film polymeric device according to claim 11, wherein the thin film polymeric device is a photovoltaic device.

14. A method of making a nanocomposite device comprising:
providing a mixture comprising a polymer, semiconducting nanoparticles, and a semiconducting molecule having a field-effect mobility of at least 0.1 cm²/Vs or a soluble precursor thereof;
depositing the mixture on a substrate; and
treating the mixture under conditions effective to produce a thin film nanocomposite device comprising the polymeric matrix, semiconducting nanoparticles, and the semiconducting molecule having a field-effect mobility of at least 0.1 cm²/Vs.

15. The method according to claim 14, wherein the polymeric matrix is poly-N-vinyl carbazole, poly(phenylene-vinylene), a polythiophene, or polyaniline.

16. The method according to claim 15, wherein the polymeric matrix is poly-N-vinyl carbazole.

17. The method according to claim 15, wherein the polymeric matrix is poly(3-hexylthiophene).

18. The method according to claim 14, wherein the semiconducting nanoparticles are quantum dots, core-shell semiconductor nanoparticles, bipods, tripods, or tetrapods.

19. The method according to claim 18, wherein the semiconducting nanoparticles are quantum dots selected from the group consisting of ZnSe, ZnS, ZnTe, CdSe, CdS, CdTe, InP, InAs, InSb, PbSe, PbS, and PbTe.

20. The method according to claim 14, wherein the semiconducting molecule having a field-effect mobility of at least 0.1 cm²/Vs is a polycyclic aromatic compound or metal chalcogenide.

21. The method according to claim 20, wherein the semiconducting molecule having a field-effect mobility of at least 0.1 cm²/Vs is a polycyclic aromatic compound.

22. The method according to claim 21, wherein the semiconducting molecule having a field-effect mobility of at least 0.1 cm²/Vs is pentacene.

23. The method according to claim 14, wherein the device comprises 37 to 60 wt % polymer, 5 to 25 wt % semiconducting nanoparticles, and 15 to 37 wt % semiconducting molecule having a field-effect mobility of at least 0.1 cm²/Vs.

24. The method according to claim 14, wherein treating comprises drying the mixture to form a nanocomposite film.

25. The method according to claim 24, wherein treating further comprises converting the soluble precursor for the semiconducting molecule having a field-effect mobility of at least 0.1 cm²/Vs into the semiconducting molecule having a field-effect mobility of at least 0.1 cm²/Vs.
